(19) United States
(12) Patent Application Publication
(10) Pub. No.: US 2007/0145581 A1
(43) Pub. Date: Jun. 28, 2007

(54) Control unit

(75) Inventor: Wataru Yagishita, Numazu-shi (JP)

Correspondence Address: PEARNE & GORDON LLP, 1801 EAST 9TH STREET, SUITE 1200, CLEVELAND, OH, 44114-3108, US

(73) Assignee: Kokusan Denki Co., Ltd., Numazu-shi (JP)

(21) Appl. No.: 11/645,938

(22) Filed: Dec. 27, 2006

(30) Foreign Application Priority Data
Dec. 27, 2005 (JP) 2005-375459

(51) Int. Cl. H01L 23/34

(52) U.S. Cl. 257/726

(57) ABSTRACT

A control unit having a package in which at least a part of components of a control system controlling specified controlling objects is housed, wherein a pair of protrusions is provided on each of opposite side surfaces of the package, and supporting members which operate as a vibration proof material are provided on each of opposite side surfaces of the package, wherein the pair of protrusions provided each of side surfaces of the package is fitted into a corresponding pair of holes of the supporting members to mount the supporting members on each of opposite side surfaces, and wherein transmission of vibration from the mounting portion to the package is prevented by mounting the package on the mounting portion through the supporting members.

### TECHNICAL FIELD OF THE INVENTION

This invention pertains to a control unit which comprises a control system or a part of the control system for controlling a specified control object of machines generating vibration such as an engine, a vehicle driven by an engine, or an engine generator.

### BACKGROUND OF THE INVENTION

In a control system for controlling a specified control object of machines generating vibration such as an engine, a vehicle driven by an engine, or an engine generator, at least a part of components of the control system is housed in a package consisting of resin molding or the like to construct a control unit, and the control unit is secured on a predetermined mounting portion provided on a part of the machine generating vibration.

Since the control unit of this kind always receives vibration, a vibration proof material is mounted on the package in order to protect the components, and the package is secured to the mounting portion through the vibration proof material. FIG. 6 shows a conventional control unit 1 of this kind. In this figure, a reference numeral 2 denotes a package which is formed so that the whole package shows a rectangular prism to house the components of the control system therein, 3 denotes a connector mounted on one side surface of the package 2, and 4 denotes a tubular rubber cover mounted on the package 2 as a vibration proof material.

The rubber cover 4 is formed into the shape of a duct, and a hole 4a, which longitudinal both ends are opened, is formed inside of the rubber cover 4 as shown in FIG. 7. The rubber cover 4 is attached on an outer periphery of the package 2 by pressing the package 2 into the hole 4a of the rubber cover. Protrusions 403 and 404 extending in the longitudinal direction of the rubber cover 4 are provided on opposite side walls 401 and 402 of the rubber cover 4, and slits 405 and 406 extending along the altitude direction of the rubber cover 4 are provided through the projections 403 and 404.

To fix the control unit shown in FIG. 6 to a predetermined mounting portion, for example, a U-shaped mounting plate is fixed to the mounting portion, and opposite plate portions of the U-shaped mounting plate is fixed into the slits 405 and 406 of the rubber cover. A control unit of this kind is disclosed in, for example, Japanese Utility Model Application Laid-open Publication No. 62-87180.

As shown in FIG. 6, since it is necessary to prepare different rubber covers specially designed for packages of different sizes when the tubular rubber cover is mounted on the package, increase in cost of the control unit was unavoidable

Also, in order to prevent the control unit from coming out from the rubber cover, it is necessary to make a cross sectional area of the hole 4a of the rubber cover 4 smaller than that of the package 2 to fit the rubber cover into the outer periphery of the package. Thus, it is unavoidable that the manufacturing efficiency of the control unit lowers because of a troublesome procedure of fitting the package into the rubber cover 4.

### SUMMARY OF THE INVENTION

Accordingly, it is a principal object of the invention to provide a control unit adapted to improve the manufacturing efficiency by simplifying attachment of a vibration proof material to a package.

The present invention is applied to a control unit comprising at least a part of components of a control system controlling specified controlling objects and a package in which the components are contained, where the package is fixed at a mounting portion where vibrations may be transmitted.

In the present invention, supporting members being consisted of an elastic material which are put in a vibration transmitting passage between the mounting portion and the package are mounted on opposite side surfaces of the package, respectively, and the package is constituted so as to be fixed on the mounting portion through the supporting members.

The mounting of the supporting members to the side surfaces of the package can be performed easily by using suitable means such as adhesion, screwing and welding. Thus, if the supporting members being consisted of an elastic material are attached on each of opposite side surfaces to fix the package to the mounting portion through the supporting members as aforementioned, mounting of the vibration proof material becomes easier compared with the case where the package is fitted with the rubber cover, which causes improvement of the manufacturing efficiency of the control unit.

Although the mounting of the supporting members to the side surfaces of the package can be performed easily by using suitable means such as adhesion, screwing and welding, it is preferable to mount the supporting members on the package with single operation in order to simplify assembling of the control unit.

In a preferred mode of the invention, a pair of protrusions arranged with a space is provided on each of opposite side surfaces of the package. Also, there are provided supporting members being consisted of an elastic material and being formed with a pair of holes through which the above-mentioned one pair of protrusion is penetrated, and the pair of protrusion is fitted into the pair of holes of the supporting members so as to support the supporting member on the side surfaces of the package. On each tip portion of the protrusions which passes through each hole of the supporting members and is protruded outward, there are formed detents which engage with the periphery of the opening portions of the holes of the supporting members to seize the supporting members. By the seizure of the detents, the supporting members are supported so as not to be slipped off from the protrusions.

With the aforementioned construction, since it is possible to mount the supporting members on the package with single operation, the assembling of the control unit can be easily performed, and thus the manufacturing efficiency of the control unit can be improved.

As described above, according to the present invention, the supporting members being consisted of the elastic material are mounted on the opposite side surfaces of the package, respectively, and the package is fixed on the mounting portion through the supporting members. Therefore, the mounting of the vibration proof material becomes easier compared with the case where the package is fitted with the rubber cover, which causes improvement of the manufacturing efficiency of the control unit.

Especially, in case that the pair of protrusion having the detents on the tip is provided on the side surfaces of the package to mount the supporting members on the package by fitting these protrusions into the holes being provided on the supporting members, the mounting of the supporting members on the package can be performed with single operation, the attachment of the supporting member can be simplified, and thus the manufacturing efficiency of the control unit can be improved.

### BRIEF DESCRIPTION OF THE DRAWINGS

The above and other objects and features of the invention will be apparent from the detailed description of the preferred embodiments of the invention, which is described and illustrated with reference to the accompanying drawings, in which;

FIG. 1 is a plan view of a control unit in accordance with one embodiment of the invention, in a condition before supporting members are mounted on a package;

FIG. 2 is a perspective view of the supporting members used in the embodiment of the invention;

FIG. 3 is a front view of a control unit in accordance with the embodiment of the invention, where the supporting members are mounted on the package;

FIG. 4A illustrates a front view showing an example in a condition where the control unit in accordance with the present invention is mounted on a mounting portion through a mounting plate, and FIG. 4B illustrates a side view of the mounting plate used in this example;

FIG. 5A illustrates a front view showing an another example in a condition where the control unit in accordance with the present invention is mounted on a mounting portion through a mounting plate, and FIG. 4B illustrates a side view of the mounting plate used in this example;

FIG. 6 shows a plan view of a conventional control unit; and

FIG. 7 shows a perspective view of a rubber cover which is used as a vibration proof material in the conventional control unit.

### DETAILED DESCRIPTION OF PREFERRED EMBODIMENTS

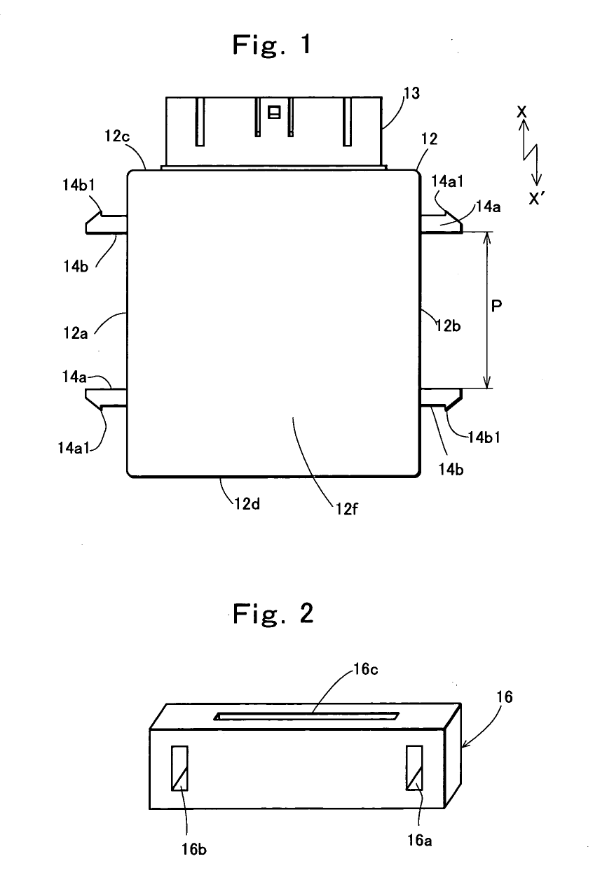

Now, the embodiments of the invention will be illustrated and described with reference to FIGS. 1 through 5B.

In FIGS. 1, 3, 4A and 4B, a reference numeral 12 denotes a package in a shape of a flat rectangle prism having: side surfaces 12a and 12b which are faced each other in the cross direction; side surfaces 12c and 12d which are faced each other in the longitudinal direction; and a bottom surface 12e and an upper surface 12f which are faced at a right angle relative to the opposite direction of the side surfaces 12a and 12b and the side surfaces 12c and 12d. This package is made of a resin molding or the like. The package 12 contains all or a part of components of a control system (for example, an ECU) for controlling a specific control object such as an ignition system for and engine and a fuel injection system. On the side surface 12c at a longitudinal end of the package 12, a connector 13 for connecting a circuit in the package to an outside circuit is attached.

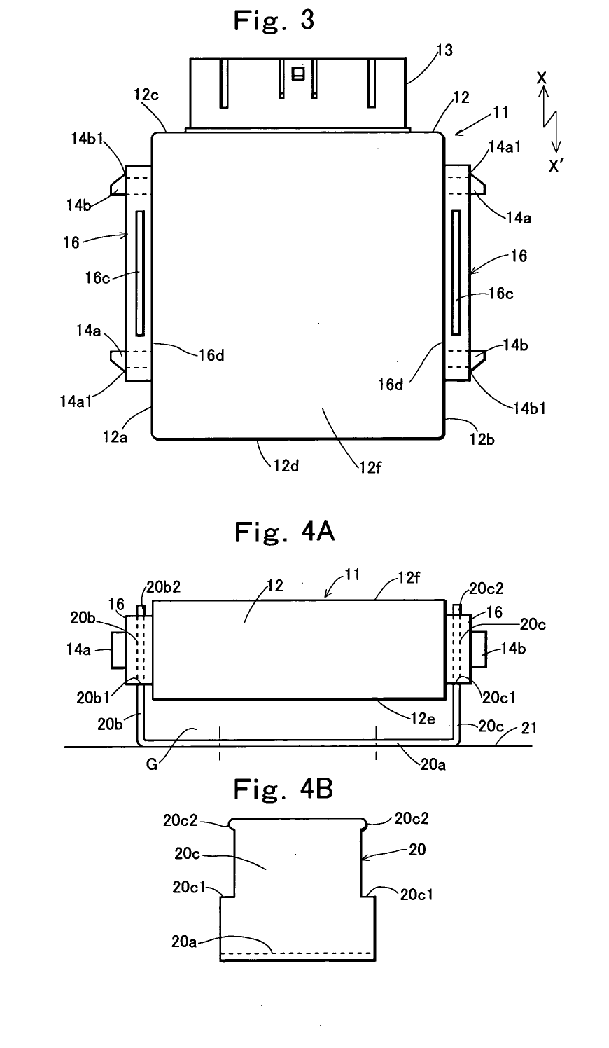

As shown in FIG. 3, there are mounted strip-shaped supporting members 16, 16 being consisted of elastic material such as rubber on the side surfaces 12a and 12b faced each other in the cross direction of the package. As shown in FIG. 2, holes 16a and 16b passing through the supporting member in the thickness direction are formed around longitudinal both ends of the supporting member 16, and a slit 16c passing through the supporting members 16 in the cross direction is formed between the holes 16a and 16b.

The supporting members 16, 16 are attached in a condition where each longitudinal direction and cross direction of the supporting members is directed toward each longitudinal direction (X-X′ direction in FIGS. 1 and 3) and thickness direction (the direction perpendicularly intersecting with drawing sheets showing FIGS. 1 and 3) respectively to contact the end surface 16d on one end side in the thickness direction with the opposite side surfaces 12a and 12b of the package 12.

Each slit 16c of the supporting members 16 is provided so as to extend in the perpendicular direction (the altitude direction of the package) relative to the bottom surface 12e and the upper surface 12f while the both supporting members are mounted on the package 12.

In order to mount the supporting members, a pair of protrusions 14a and 14b being arranged with a space P in the longitudinal direction of the package is formed on each of the side surfaces 12a and 12b which are opposed in the cross direction of the package 12. On tips of the protrusions 14a and 14b, there are formed detents 14a1 and 14b1 protruded outward from each one end of the cross direction of the protrusions.

The pair of the protrusions 14a and 14b on each side surface of the package is fitted into the pair of holes 16a and 16b of the supporting member 16, the supporting members 16 are supported by the fitting of the holes 16a, 16b and the protrusions 14a, 14b. Also, the detents 14a1 and 14b1, which are formed on each tip portion of the pair of protrusions 14a and 14b protruded outward while passing through each of the pair of holes of the supporting members, engage with the periphery of the opening of the holes 16a and 16b to seize the supporting member 16, which prevents the supporting members from coming out from the protrusions 14a and 14b.

When the control unit of the present invention is set to a mounting portion, a bottom plate 20a of a U-shape mounting plate 20 having the bottom plate 20a and side plates 20b, 20c is fixed to a mounting surface of the mounting portion 21; then, the side plates 20b, 20c of the mounting plate are fitted with the slits 16c, 16c of the supporting members 16, 16 mounted on the opposite surfaces 12a and 12b of the package, respectively, in order to unite the supporting members 16 and the mounting plate 20.

In this case, parts for receiving the supporting members 16 at a position apart from the mounting surface of the mounting portion 21 are provided on the side plates 20b and 20c of the mounting plate 20 so as to support the package 12 through the supporting members 16, in a state where the bottom surface 12e of the package is opposed to the bottom plate 20a of the mounting plate 20 through a predetermined gap G. In the example shown in FIG. 4B, width of lower parts, near the bottom plate 20a, of the side plates 20b and 20c are enlarged to form steps 20b1 and 20c1 between the enlarged parts and the other parts of side plates 20b and 20c. The supporting members 16, 16 are received by steps 20b1 and 20c1 of the side plates 20b and 20c, and the bottom surface 12e of the package 12 is come up from the bottom plate 20a of the mounting plate 20 so as to from the gap G between the bottom surface 12e and the bottom plate 20a. Also, the size of width of the tips of the side plate 20b and 20c arranged in a condition penetrating from the end portion opposed to the mounting portion of the supporting members 16 is slightly enlarged to form seizing portions 20b2 and 20c2 so that the package 12 does not come off from the side plates 20b and 20c of the mounting plate.

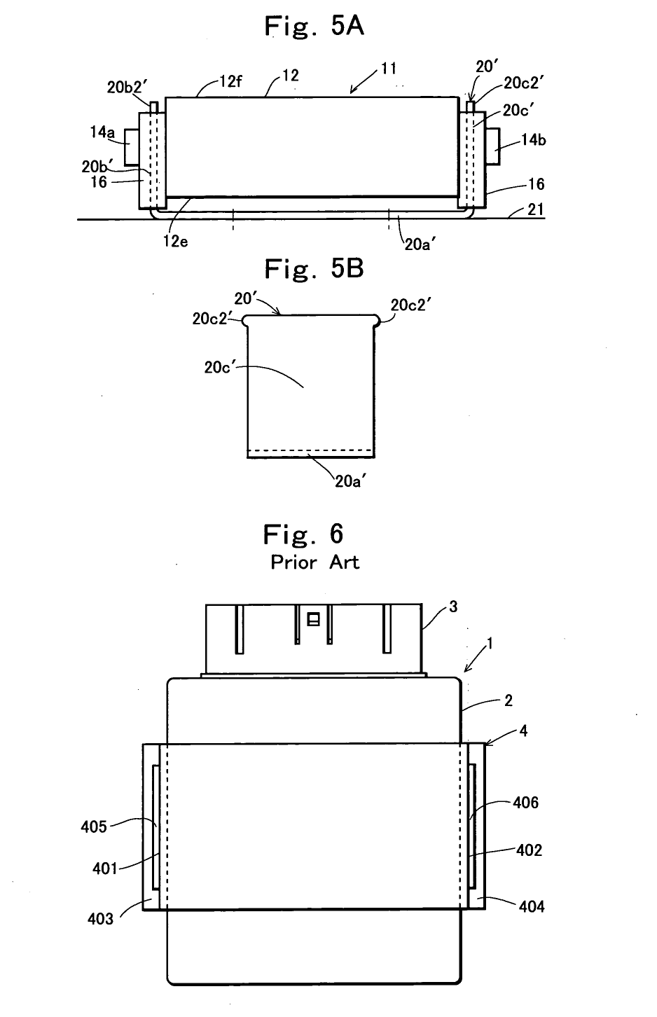

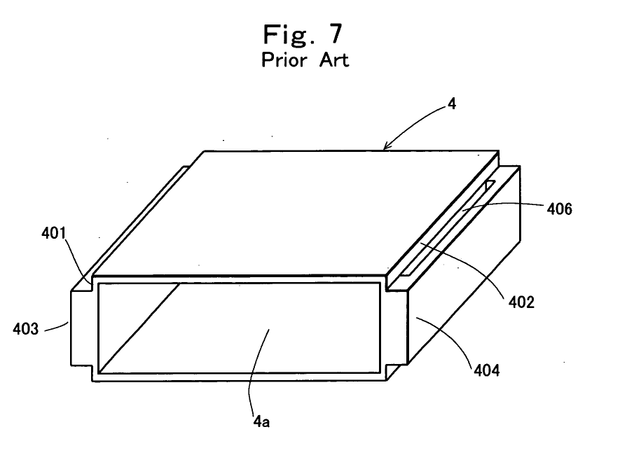

As shown in FIG. 5B, instead of forming the parts for receiving the supporting members 16, 16 on the side plates 20b and 20c as stated above, the package 12 may be fixed to the mounting portion 21 by inserting side plates 20b′ and 20c′ of a mounting plate 20′ into the slits of the supporting members 16, 16, while end portions of the supporting members 16 which are opposed to the mounting portion 21 are deviated from the end portions of the package 12 toward the mounting portion 21 as shown in FIG. 5A so as to fix the package 12 to the mounting portion 21 in the condition that the bottom surface 12e of the package comes up from a bottom plates 20a′ of the mounting plate 20′. Also, in this case, the size of width of the tips of the side plate 20b′ and 20c′ arranged in a condition penetrating from the end portion opposed to the mounting portion of the supporting members 16 is slightly enlarged to form seizing portions 20b2′ and 20c2′ so that the package 12 does not come off from the side plates 20b and 20c of the mounting plate.

As aforementioned, it is possible to prevent vibration from transmitting from the mounting portion to the package, since the supporting members 16, 16 are put in a vibration transmitting passage from the mounting portion to the package when the supporting members 16, 16 being consisted of a elastic material are mounted on opposite side surfaces of the package 12, respectively, to fix the package 12 on the mounting portion 21 through the supporting members. Therefore, in case of mounting a control unit on a machine on which a vibration source such as an engine is provided, a damage of components, which is caused by large vibration transmitted to the components of the control unit, can be prevented.

In addition, when the supporting members 16, 16 being consisted of the elastic material are mounted on the opposite side surfaces of the package 12, respectively, as vibration proof material, the mounting of the vibration proof material becomes easier compared with a case where the package is fitted with the rubber cover, which causes improvement of manufacturing efficiency of the control unit.

Especially, in case that the pair of protrusion 14a and 14b having the detents on the tip is provided on the side surfaces of the package to mount the supporting members on the package by fitting these protrusions into the holes 16a and 16b being provided on the supporting members 16 as described in the above embodiment, the mounting of the supporting members 16 on the package 12 can be performed with a single operation, the attachment of the supporting member can be simplified, and thus the manufacturing efficiency of the control unit can be improved.

In case that the size of the package varies, the same supporting members can be used if a distance P (refer to FIG. 1) between the protrusions 14a and 14b is identical. Thus, reduction in cost can be made by standardizing supporting members for control units of different specifications.

Although some preferred embodiments of the invention have been described and illustrated with reference to the accompanying drawings, it will be understood by those skilled in the art that they are by way of examples, and that various changes and modifications may be made without departing from the spirit and scope of the invention, which is defined only to the appended claims.

What is claimed is:

1. A control unit comprising at least a part of components of a control system controlling specified controlling objects and a package in which said components are contained, said package being fixed at a mounting portion where vibrations may be transmitted,
wherein supporting members being consisted of a elastic material which are put in a vibration transmitting passage between said mounting portion and said package are mounted on opposite side surfaces of said package, respectively, and
wherein said package is constituted so as to be fixed on said mounting portion through said supporting members.

2. A control unit as set forth in claim 1 and wherein a slit for fitting a mounting plate which is used when said package is fixed on said mounting portion is formed through each of said supporting members.

3. A control unit comprising at least a part of components of a control system controlling specified controlling objects and a package in which said components are contained, said package being fixed at a mounting portion where vibrations may be transmitted,
wherein a pair of protrusions arranged with a space is provided on each of opposite side surfaces of said package,
wherein there are provided strip-shaped supporting members being consisted of an elastic material and being formed with a pair of holes through which said pair of protrusions is passed, and said pair of protrusions is fitted into said pair of holes of the supporting members so as to support the supporting member on the side surfaces of said package, and
wherein, on each tip portion of the protrusions which passes through each hole of the supporting members and is protruded outward, there are formed detents which engage with periphery of opening portions of the holes of said supporting members to seize the supporting members.

4. A control unit as set forth in claim 3 and wherein a slit for fitting a mounting plate which is used when said package is fixed on said mounting portion is formed through each of said supporting members.
